(19) United States
(12) Patent Application Publication
(10) Pub. No.: US 2025/0251437 A1
(43) Pub. Date: Aug. 7, 2025

(54) CIRCUIT FOR STRESS TESTING POWER TRANSISTOR GATES

(71) Applicant: STMicroelectronics International N.V., Geneva (CH)

(72) Inventors: Kuno LENZ, Voreppe (FR); Philippe SIRITO-OLIVIER, Martigues (FR); David DELSALLE, Grenoble (FR)

(73) Assignee: STMicroelectronics International N.V., Geneva (CH)

(21) Appl. No.: 19/033,183

(22) Filed: Jan. 21, 2025

(30) Foreign Application Priority Data
Feb. 5, 2024 (FR) FR2401084

(51) Int. Cl. G01R 31/26; G01R 31/27; H02M 3/00

(52) U.S. Cl. CPC G01R 31/2621; G01R 31/27; H02M 3/003

(57) ABSTRACT

Provided is a power electronic circuit comprising at least one power transistor the gate of which is coupled to a control circuit, and the source of which is coupled to a first contact pad, wherein the control circuit is coupled to a second contact pad, and wherein the first and second contact pads are configured to be decoupled from each other when the power electronic circuit is in a configuration for stress testing the gate of the power transistor, and configured to be coupled to each other when the power transistor and control circuit are encapsulated.

### BACKGROUND

### Technical Field

The present description relates generally to the field of power electronic circuits comprising power transistors, in particular DC-DC converters, or direct current-direct current converter.

### Description of the Related Art

During the production of power circuits such as DC-DC converters, the power transistors of these circuits (for example, forming the switching cells in the case of a converter) are tested in order to discard circuits comprising transistors that do not comply with the required specifications, and to use those comprising transistors that do comply with these specifications. One such test, referred to as a gate stress test, involves applying a high voltage, referred to as a stress voltage, between the gate and the source of the power transistor under test. For example, this stress voltage could be equal to 11 V and could be applied for a duration of 200 ms. For a PMOS transistor, the stress voltage applied between the gate and source of the transistor is negative, to avoid PBTI-type degradation (positive bias temperature instabilities).

This stress voltage is much higher than the nominal supply voltage, e.g., 5 V or 7 V, applied during “conventional” switching or operating use of these transistors. This stress testing of power transistor gates enables to identify the presence of defects in the transistors under test, for example in their gate oxide, which could lead to significant leakage currents after a short period of transistor use (e.g., after about a year). Leakage in transistors with such defects therefore appears during stress testing, and power circuits comprising these faulty transistors could thus be identified and discarded without waiting for such leakage to appear during use.

During stress testing, other circuit components coupled to the connections to which the stress voltages are applied, such as components of the control circuit of the power transistor, are protected from being destroyed by the stress voltages. For example, in the case of a switching circuit comprising a CMOS inverter, this protection could be achieved by adding an additional transistor coupled to an electrical resistor at the output of the inverter.

Further, dedicated internal contact pads are used during stress testing transistors to measure leakage currents, as well as for the application of stress voltage for power transistors on the low-side of the circuit.

Finally, because the drains of the power transistors on the high-side and low-side of the circuit are coupled to the same contact pad from which the output signal of the power transistors is recovered, it is not possible to test the power transistors on the high-side and low-side of the power circuit at the same time.

### BRIEF SUMMARY

There is a need for providing a solution that does not have at least some of the drawbacks of existing solutions.

One embodiment overcomes some or all of the drawbacks of the known solutions and provides a power electronic circuit comprising at least one power transistor the gate of which is coupled to a control circuit, and the source of which is coupled to a first contact pad, wherein the control circuit is coupled to a second contact pad, and wherein the first and second contact pads are configured to be decoupled from each other when the power electronic circuit is in a configuration for stress testing the gate of the power transistor, and configured to be coupled to each other when the power transistor and control circuit are encapsulated.

According to one embodiment, the power transistor and the control circuit are high-side components of the power electronic circuit, and the first and second contact pads are configured so that different electrical supply potentials are applied to each of them when the power electronic circuit is in the configuration for stress testing the gate of the power transistor.

According to one embodiment, the power transistor and the control circuit are low-side components of the power electronic circuit, and the first and second contact pads are configured so that different electrical reference potentials are applied to each of them when the power electronic circuit is in the configuration for stress testing the gate of the power transistor.

According to one embodiment:
the power transistor, referred to as the first power transistor, and the control circuit, referred to as the first control circuit, are high-side components of the power electronic circuit, and
the power electronic circuit further comprises a second power transistor the gate of which is coupled to a second control circuit, and the source of which is coupled to a third contact pad, the second control circuit being coupled to a fourth contact pad, the second power transistor and the second control circuit corresponding to low-side components of the power electronic circuit, and
the first and second contact pads are configured so that different electrical supply potentials are applied to each of them when the power electronic circuit is in a configuration for stress testing the gates of the first and second power transistors, and
the third and fourth contact pads are configured to be decoupled from each other and to have different electrical reference potentials applied to each of them when the power electronic circuit is in the configuration for stress testing the gates of the first and second power transistors, and configured to be coupled to each other when the first and second power transistors and the first and second control circuits are encapsulated.

According to one embodiment, the drain of the first power transistor is coupled to a first switching pad, and the drain of the second power transistor is coupled to a second switching pad, and the first and second switching pads are configured to be decoupled from each other when the power electronic circuit is in the configuration for stress testing the gates of the first and second power transistors and configured to be coupled to each other when the first and second power transistors and the first and second control circuits are encapsulated.

According to one embodiment, the control circuit, or each of the first and second control circuits, includes a CMOS inverter the output of which is coupled to the gate of the power transistor, or one of the first and second power transistors, and/or the power transistor, or each of the first and second power transistors, corresponds to a MOSFET.

According to one embodiment, the power electronic circuit includes an encapsulation element.

According to one embodiment, the power electronic circuit further includes a first electrical connector electrically coupling together the first and second contact pads, and, when the power electronic circuit includes third and fourth contact pads, a second electrical connector coupling together the third and fourth contact pads.

According to one embodiment, the power electronic circuit includes first and second switching pads and a third electrical connector coupling together the first and second switching pads.

According to one embodiment, the power electronic circuit is a DC-DC converter.

It is also provided a method for implementing and encapsulating at least one power electronic circuit, including at least the following steps:
implementing the power electronic circuit as described above;
performing a stress test of the gate(s) of the power transistor(s) of the power electronic circuit;
encapsulating the power transistor(s) and control circuit(s) of the power electronic circuit.

According to one embodiment, stress testing the gate(s) of the power transistor(s) includes measuring a leakage current on the first contact pad and/or on the third contact pad.

According to one embodiment, encapsulating the power transistor(s) and control circuit(s) includes performing a first electrical connector electrically coupling together the first and second contact pads of the power electronic circuit, and, when the power electronic circuit includes third and fourth contact pads, performing a second electrical connector coupling together the third and fourth contact pads of the power electronic circuit.

According to one embodiment, encapsulating the power transistor(s) and control circuit(s) further includes performing a third electrical connector coupling together the first and second switching pads of the power electronic circuit.

### BRIEF DESCRIPTION OF DESCRIPTION OF THE RELATED DRAWINGS

The foregoing features and advantages, as well as others, will be described in detail in the following description of specific embodiments given by way of illustration and not limitation with reference to the accompanying drawings, in which:

FIG. 1 illustrates schematically an example part of a power electronic circuit according to one specific embodiment, in a configuration for stress testing the gates of the power transistors of the circuit;

FIG. 2 illustrates schematically an example of part of a power electronic circuit according to one specific embodiment, after interconnecting the contact pads of the circuit; and

FIG. 3 illustrates schematically a power electronic circuit the components of which are encapsulated, according to one specific embodiment.

### DETAILED DESCRIPTION

Like features have been designated by like references in the various figures. In particular, the structural and/or functional features that are common among the various embodiments could have the same references and could dispose identical structural, dimensional and material properties.

For the sake of clarity, only the operations and elements that are useful for an understanding of the embodiments described herein have been illustrated and described in detail. In particular, various elements and components of the power electronic circuit are not described in detail. Those skilled in the art will be able to perform these elements in detail from the description given here.

Unless indicated otherwise, when reference is made to two elements connected together, this signifies a direct connection without any intermediate elements other than conductors, and when reference is made to two elements coupled together, this signifies that these two elements could be connected or they could be coupled via one or more other elements. Furthermore, the term “coupled” is used here to designate an electrical coupling between several electrical and/or electronic elements (components, circuits, etc.). The same applies to the term “decoupled”.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures, as orientated during normal use.

Unless specified otherwise, the expressions “around,” “approximately,” “substantially” and “in the order of” signify within 10%, and preferably within 5%.

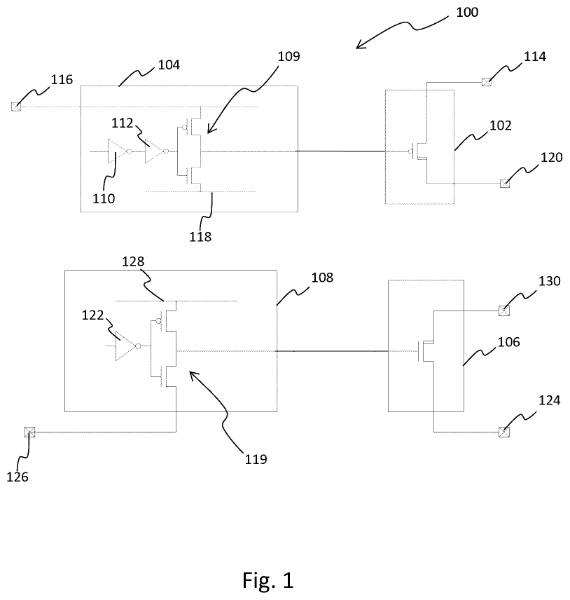

A power electronic circuit 100 according to one specific embodiment is described below in connection with FIG. 1. Only part of the elements and components of the circuit 100 are described below and visible on FIG. 1.

The circuit 100 includes electrical and/or electronic elements or components on a high-side part of the circuit 100, to which at least one electrical supply potential of the circuit 100 is intended to be applied. The circuit 100 also includes electrical and/or electronic elements or components on a low-side part of the circuit 100, to which at least one electrical reference potential of the circuit 100, e.g., acting as ground, is intended to be applied.

In the described example embodiment, the circuit 100 includes one or more first power transistors 102, as well as one or more first control circuits 104 being part of the high side of the circuit 100. The first control circuits 104 are configured to control the switching of the first power transistors 102. When the circuit 100 includes several first power transistors 102, the gate of each of these first power transistors 102 is coupled to the output of a first control circuit 104 dedicated to the control of this transistor.

Circuit 100 also includes one or more second power transistors 106, and one or more second control circuits 108 being part of the low side of circuit 100. The second control circuits 108 are configured to control the switching of the second power transistors 106. When the circuit 100 includes several second power transistors 106, the gate of each of these second power transistors 106 is coupled to the output of a second control circuit 108 dedicated to the control of this transistor.

In FIG. 1, a single first power transistor 102, a single first control circuit 104, a single second power transistor 106, and a single second control circuit 108 are shown. The features described below for each of these components could also apply to other power transistors and control circuits of the circuit 100 not shown in FIG. 1.

In the described example embodiment, power transistors 102, 106 and control circuit transistors 104, 108 are MOSFETs. Alternatively, other types of transistors could be used to form the power transistors 102, 106 and/or the transistors of the control circuits 104, 108.

In the example shown in FIG. 1, the first power transistor 102 corresponds to a PMOS transistor the gate of which is coupled to the first control circuit 104. More specifically, in the example embodiment described, the gate of the first power transistor 102 is coupled to the output of a first CMOS inverter 109 of the first control circuit 104 (this output being coupled to the drains of the NMOS and PMOS transistors of the first CMOS inverter 109). In the example shown in FIG. 1, the input of the first CMOS inverter 109 (which is coupled to the gates of the NMOS and PMOS transistors of the first CMOS inverter 109) is coupled to two inverters 110, 112 coupled in series with each other.

The source of the first power transistor 102 is coupled to a first contact pad 114, and the first control circuit 104 is coupled to a second contact pad 116. In the example shown in FIG. 1, it is the source of the PMOS transistor of the first CMOS inverter 109 that is coupled to the second contact pad 116. In this example, the source of the NMOS transistor of the first CMOS inverter 109 is coupled to a floating ground 118. Finally, the drain of the first power transistor 102 is coupled to another contact pad referred to as the first switching pad 120.

In the example shown in FIG. 1, the second power transistor 106 corresponds to an NMOS transistor the gate of which is coupled to the second control circuit 108. More specifically, in the example embodiment described, the gate of the second power transistor 106 is coupled to the output of a second CMOS inverter 119 of the second control circuit 108 (this output being coupled to the drains of the NMOS and PMOS transistors of the second CMOS inverter 119). In the example shown in FIG. 1, the input of the second CMOS inverter 119 (which is coupled to the gates of the NMOS and PMOS transistors of the second CMOS inverter 119) is coupled to an inverter 122.

The source of the second power transistor 106 is coupled to a third contact pad 124, and the second control circuit 108 is coupled to a fourth contact pad 126. In the example shown in FIG. 1, it is the source of the NMOS transistor of the second CMOS inverter 119 that is coupled to the fourth contact pad 126. In this example, the source of the PMOS transistor of the second CMOS inverter 119 is coupled to a floating electrical supply potential 128. Finally, the drain of the second power transistor 106 is coupled to another contact pad referred to as the second switching pad 130.

In the example shown in FIG. 1, the components of circuit 100 are not yet encapsulated. The circuit 100 is therefore in a configuration in which the connections between pads 114 and 116, between pads 124 and 126, and between pads 120 and 130 have not yet been performed, and therefore in a configuration in which stress testing the gates of power transistors 102, 106 could be implemented. In this test configuration, the first and second contact pads 114, 116 are decoupled from each other. Thus, when stress testing the power transistors, different electrical supply potentials could be applied to each of the first and second contact pads 114, 116, enabling a lower electrical supply voltage to be applied to the first control circuit 104 than the stress voltage applied between the gate and the source of the first power transistor 102, and thus damage to the first control circuit 104 that would be caused by the application of the stress voltage to the first control circuit 104 to be avoided.

For example, during stress testing the first power transistor 102, a first electrical supply potential, for example equal to 11 V, could be applied to the first contact pad 114, and a second electrical supply potential lower than the first electrical supply potential, for example equal to 5 V, could be applied to the second contact pad 116. The electrical potential of the floating ground 118 could be equal to 0 V. In this case, by applying an electrical potential corresponding to a logic ‘1’ at the input of inverter 110, for example equal to 5 V, the electrical potential obtained at the output of first CMOS inverter 109 and applied to the gate of first power transistor 102 is zero. Another electrical supply potential equal to the first electrical potential could be applied to the first switching pad 120 during stress testing the first power transistor 102.

Similarly, in this stress testing configuration, the third and fourth contact pads 124, 126 are decoupled from each other. Thus, when stress testing the power transistors, different electrical reference potentials could be applied to each of the third and fourth contact pads 124, 126, enabling, as with components on the high side of the circuit 100, a lower supply voltage to be applied to the second control circuit 108 than the stress voltage applied between the gate and source of the second power transistor 106.

For example, during stress testing the second power transistor 106, a first reference electrical potential equal to −6 V could be applied to the third contact pad 124, and a second reference electrical potential higher than the first reference electrical potential, for example equal to 0 V, could be applied to the fourth contact pad 126. The floating supply potential 128 could be equal to 5 V. In this case, by applying an electrical potential corresponding to a logic ‘1’ at the input of inverter 122, for example equal to 5 V, the electrical potential obtained at the output of second CMOS inverter 119 and applied to the gate of second power transistor 106 is equal to 5 V. Another electrical reference potential equal to the first electrical reference potential could be applied to the second switching pad 130 during stress testing the second power transistor 106.

In this test configuration, as shown in FIG. 1, the first and second switching pads 120, 130 are thus decoupled from each other. Stress testing the first and second power transistors 102, 106 could thus be carried out simultaneously.

During stress testing the power transistors 102, 106, a leakage current from the first power transistor 102 could be measured on the first contact pad 114, and/or a leakage current from the second power transistor 106 could be measured on the third contact pad 124. Alternatively, it is possible for the first power transistor 102 to include a Kelvin source connection allowing any leakage current to be measured, in which case the output of the first CMOS inverter 109 is set to a high-impedance configuration during stress testing this transistor, and/or for the second power transistor 106 to include a Kelvin source connection allowing any leakage current to be measured, in which case the output of the second CMOS inverter 119 is set to a high-impedance configuration during stress testing this transistor.

The above-described implementation of stress testing the gates of power transistors 102, 106 allows revealing whether one or more of these power transistors 102, 106 have faults generating leakage currents. In the presence of such faults, the circuit 100 is discarded and not used. Thanks to the structure of circuit 100, stress testing power transistors 102, 106 could be carried out without subjecting control circuits 104, 108 to the high stress voltages used during these tests, thus protecting them from these voltages without having to resort to additional components dedicated to protecting control circuits 104, 108. Further, Thanks to the first and second switching pads 120, 130 being not coupled to each other during stress testing the power transistors 102, 106, these transistors could be tested at the same time during the same stress testing phase. In addition, with this configuration of the circuit 100, there is no need for providing contact pads dedicated solely to measuring any leakage currents and/or applying stress voltages. Finally, as there are no electronic components dedicated to protecting the control circuits 104, 108, the performance of the circuit 100, in particular its operating speed, is not altered by the presence of these protecting components.

The circuit 100 is also suitable for stress testing the drains of power transistors 102 and 106. Further, because the contact pads 114 and 116, 124 and 126, and 120 and 130 are disconnected when the components of circuit 100 are not yet encapsulated, it is possible to perform these tests in parallel on power transistors 102 and 106.

After implementing stress testing the gates of power transistors 102, 106, the components of circuit 100 are encapsulated. In the example described here, this encapsulation is carried out in such a way as to couple together:
the first and second contact pads 114, 116;
the third and fourth contact pads 124, 126;
the first and second switching pads 120, 130.

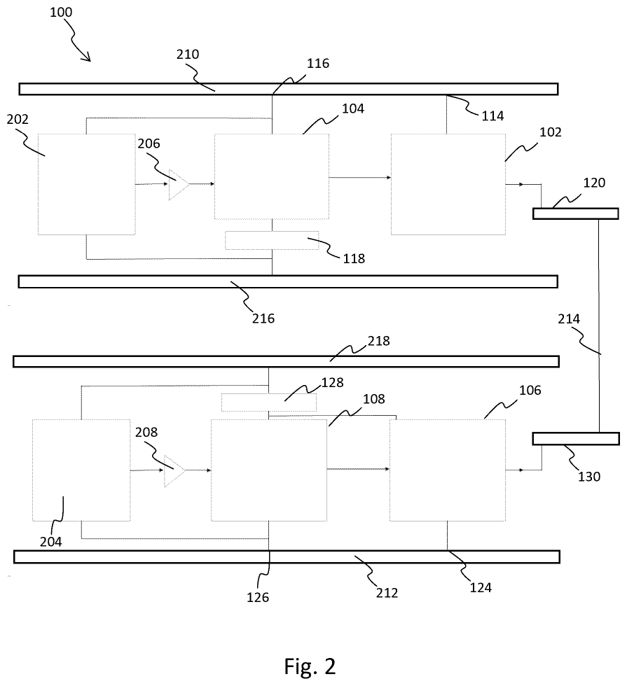

FIG. 2 illustrates schematically the components of the circuit 100 after the contact pads 114, 116, 120, 124, 126, and 130 have been interconnected during encapsulation of the components of the circuit 100. In addition to the components of the circuit 100 described above, the circuit 100 also includes analog and digital logic components, together designated by reference 202 for the high side of the circuit 100 and reference 204 for the low side of the circuit 100. Output signals from these components are sent as input to control circuits 104, 108 via level converter circuits 206, 208, enabling particularly the control circuits 104, 108 to be controlled. These components are also encapsulated.

The implemented encapsulation forms a first electrical connector 210 coupling together the first and second contact pads 114, 116. The implemented encapsulation also forms a second electrical connector 212 coupling together the third and fourth contact pads 124, 126. In the example shown in FIG. 2, the encapsulation also forms a third electrical connector 214 coupling together the first and second switching pads 120, 130. Further, in the example embodiment described, the implemented encapsulation also forms a fourth electrical connector 216 for applying a reference electrical potential to the first control circuit 104 (via the floating ground 118) and to the components 202, and a fifth electrical connector 218 for applying a supply electrical potential to the second control circuit 108 (via the floating supply 118) and to the components 204.

According to one example embodiment, electrical connectors 210 to 218 are of the DCI type (“Direct Copper Interconnection”), enabling low electrical resistance connections with pads 114, 116, 120, 124, 126, and 130. Implementing such connections between electrical connectors 210 to 218 and pads 114 and 116, 124 and 126, and 120 and 130, could be made on a panel scale, or PLP (“Panel Level Process” or “Panel Level Packaging”).

As an alternative to the embodiment described above, the components on the high side and/or low side of the circuit 100 could be different from those previously described.

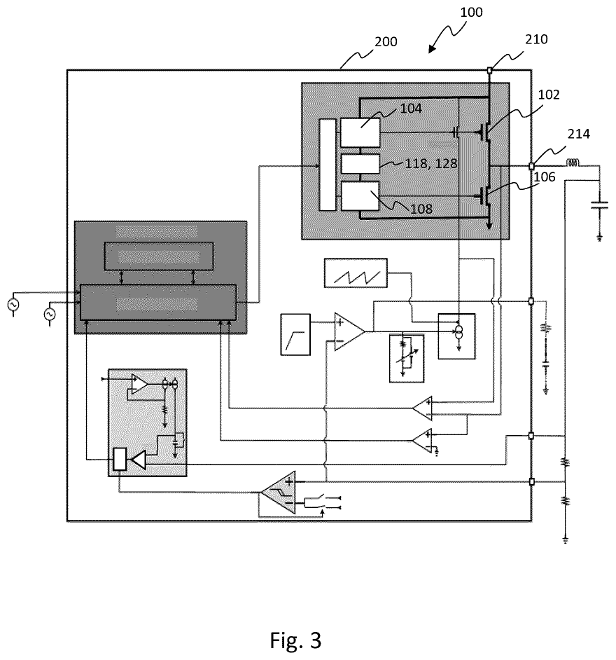

FIG. 3 illustrates schematically an example embodiment in which the power electronic circuit 100 corresponds to a step-down DC-DC converter. On this Figure, an encapsulation element 200 of the circuit 100, for example an encapsulation package or any other encapsulation means adapted to the circuit 100, is symbolically represented. The various components other than those previously described are not described in detail.

The power electronic circuit 100 could particularly apply in automotive field.

Various embodiments and variants have been described. Those skilled in the art will understand that certain features of these embodiments could be combined and other variants will readily occur to those skilled in the art.

Finally, the practical implementation of the embodiments and variants described herein is within the capabilities of those skilled in the art based on the functional description provided hereinabove.

A power electronic circuit (100) may be summarized as including at least one power transistor (102, 106) the gate of which is coupled to a control circuit (104, 108), and the source of which is coupled to a first contact pad (114, 124), wherein the control circuit (104, 108) is coupled to a second contact pad (116, 126), and wherein the first and second contact pads (114, 116, 124, 126) are configured to be decoupled from each other when the power electronic circuit (100) is in a configuration for stress testing the gate of the power transistor (102, 106), and configured to be coupled to each other when the power transistor (102, 106) and control circuit are encapsulated (104, 108).

The power transistor (102) and the control circuit (104) may be high-side components of the power electronic circuit (100), and the first and second contact pads (114, 116) may be configured so that different electrical supply potentials are applied to each of them when the power electronic circuit (100) is in the configuration for stress testing the gate of the power transistor (102).

The power transistor (106) and the control circuit (108) may be low-side components of the power electronic circuit (100), and the first and second contact pads (124, 126) may be configured so that different electrical reference potentials are applied to each of them when the power electronic circuit (100) is in the configuration for stress testing the gate of the power transistor (106).

The power transistor (102), referred to as the first power transistor, and the control circuit (104), referred to as the first control circuit, may be high-side components of the power electronic circuit (100), and the power electronic circuit (100) may further include a second power transistor (106) the gate of which may be coupled to a second control circuit (108), and the source of which may be coupled to a third contact pad (124), the second control circuit (108) being coupled to a fourth contact pad (126), the second power transistor (106) and the second control circuit (108) corresponding to low-side components of the power electronic circuit (100), and the first and second contact pads (114, 116) may be configured so that different electrical supply potentials are applied to each of them when the power electronic circuit (100) is in a configuration for stress testing the gates of the first and second power transistors (102, 106), and the third and fourth contact pads (124, 126) may be configured to be decoupled from each other and to have different electrical reference potentials applied to each of them when the power electronic circuit (100) is in the configuration for stress testing the gates of the first and second power transistors (102, 106), and configured to be coupled to each other when the first and second power transistors (102, 106) and the first and second control circuits (104, 108) are encapsulated.

The drain of the first power transistor (102) may be coupled to a first switching pad (120), and the drain of the second power transistor (106) may be coupled to a second switching pad (130), and the first and second switching pads (120, 130) may be configured to be decoupled from each other when the power electronic circuit (100) is in the configuration for stress testing the gates of the first and second power transistors (102, 106) and configured to be coupled to each other when the first and second power transistors (102, 106) and the first and second control circuits (104, 108) are encapsulated.

The control circuit (104, 108), or each of the first and second control circuits (104, 108), may include a CMOS inverter (109, 119) the output of which may be coupled to the gate of the power transistor (102, 106), or one of the first and second power transistors (102, 106), and/or the power transistor (102, 106), or each of the first and second power transistors (102, 106), corresponds to a MOSFET.

The power electronic circuit (100) may include an encapsulation element (200).

The power electronic circuit (100) may further include a first electrical connector (210) electrically coupling together the first and second contact pads (114, 116), and, when the power electronic circuit (100) may include third and fourth contact pads (124, 126), a second electrical connector (212) coupling together the third and fourth contact pads (124, 126).

The power electronic circuit (100) may include the first and second switching pads (120, 130) and a third electrical connector (214) coupling together the first and second switching pads (120, 130).

The power electronic circuit (100) may correspond to a DC-DC converter.

A method for implementing and encapsulating at least one power electronic circuit (100), may be summarized as including at least the following steps: implementing the power electronic circuit (100) according to any claim 1; performing a stress test of the gate(s) of the power transistor(s) (102, 106) of the power electronic circuit (100); encapsulating the power transistor(s) (102, 106) and control circuit(s) (104, 108) of the power electronic circuit (100).

Stress testing the gate(s) of the power transistor(s) (102, 106) may include measuring a leakage current on the first contact pad (114) and/or on the third contact pad (124).

Encapsulating the power transistor(s) (102, 106) and control circuit(s) (104, 108) may include performing a first electrical connector (210) electrically coupling together the first and second contact pads (114, 116) of the power electronic circuit (100), and, when the power electronic circuit (100) includes third and fourth contact pads (124, 126), may perform a second electrical connector (212) coupling together the third and fourth contact pads (124, 126) of the power electronic circuit (100).

Encapsulating the power transistor(s) (102, 106) and control circuit(s) (104, 108) may further include performing a third electrical connector (214) coupling together the first and second switching pads (120, 130) of the power electronic circuit (100).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A power electronic circuit comprising:
a first contact pad;
a second contact pad;
a control circuit; and
a power transistor having:
a gate coupled to the control circuit, and
a source coupled to the first contact pad,
wherein the control circuit is coupled to the second contact pad, and wherein the first and second contact pads are configured to be decoupled from each other when the power electronic circuit is in a configuration for stress testing the gate of the power transistor, and the first and second contact pads are configured to be coupled to each other when the power transistor and control circuit are encapsulated.

2. The power electronic circuit according to claim 1, wherein the power transistor and the control circuit are high-side components of the power electronic circuit, and the first and second contact pads are configured to receive different electrical supply potentials when the power electronic circuit is in the configuration for stress testing the gate of the power transistor.

3. The power electronic circuit according to claim 1, wherein the power transistor and the control circuit are low-side components of the power electronic circuit, and wherein the first and second contact pads are configured to receive different electrical reference potentials when the power electronic circuit is in the configuration for stress testing the gate of the power transistor.

4. The power electronic circuit according to claim 1, wherein:
the power transistor is a first power transistor, and the control circuit is a first control circuit, and the first power transistor and the first control circuit are high-side components of the power electronic circuit, and
the power electronic circuit includes:
a second power transistor having:
a gate coupled to a second control circuit, and
a source coupled to a third contact pad wherein the second control circuit is coupled to a fourth contact pad, and the second power transistor and the second control circuit are low-side components of the power electronic circuit, and
the first and second contact pads are configured to receive different electrical supply potentials when the power electronic circuit is in a configuration for stress testing the gates of the first and second power transistors, and
the third and fourth contact pads are configured to be decoupled from each other and to receive different electrical reference potentials when the power electronic circuit is in the configuration for stress testing the gates of the first and second power transistors, and the third and fourth contact pads are configured to be coupled to each other when the first and second power transistors and the first and second control circuits are encapsulated.

5. The power electronic circuit according to claim 4, wherein a drain of the first power transistor is coupled to a first switching pad, and a drain of the second power transistor is coupled to a second switching pad, and wherein the first and second switching pads are configured to be decoupled from each other when the power electronic circuit is in the configuration for stress testing the gates of the first and second power transistors and the first and second switching pads configured to be coupled to each other when the first and second power transistors and the first and second control circuits are encapsulated.

6. The power electronic circuit according to claim 1, wherein the control circuit includes a CMOS inverter having an output coupled to the gate of the power transistor, or the power transistor is a MOSFET.

7. The power electronic circuit according to claim 4, wherein each of the first and second control circuits includes a CMOS inverter having an output coupled to a gate of one of the first and second power transistors or each of the first and second power transistors is a MOSFET.

8. The power electronic circuit (100) according to claim 1, comprising:
an encapsulation element.

9. The power electronic circuit according to claim 8, comprising:
a first electrical connector electrically coupling the first and second contact pads.

10. The power electronic circuit according to claim 4, comprising:
a second electrical connector coupling the third and fourth contact pads.

11. The power electronic circuit according to claim 9, comprising:
first and second switching pads; and
a third electrical connector coupling the first and second switching pads.

12. A DC-DC converter, comprising:
a power electronic circuit including:
a first contact pad;
a second contact pad;
a control circuit; and
a power transistor having:
a gate coupled to the control circuit, and
a source coupled to the first contact pad,
wherein the control circuit is coupled to the second contact pad, and wherein the first and second contact pads are configured to be decoupled from each other when the power electronic circuit is in a configuration for stress testing the gate of the power transistor, and the first and second contact pads are configured to be coupled to each other when the power transistor and control circuit are encapsulated.

13. The DC-DC converter according to claim 12, wherein the power transistor and the control circuit are high-side components of the power electronic circuit, and the first and second contact pads are configured to receive different electrical supply potentials when the power electronic circuit is in the configuration for stress testing the gate of the power transistor.

14. The DC-DC converter according to claim 12, wherein the power transistor and the control circuit are low-side components of the power electronic circuit, and wherein the first and second contact pads are configured to receive different electrical reference potentials when the power electronic circuit is in the configuration for stress testing the gate of the power transistor.

15. The DC-DC converter according to claim 12, wherein:
the power transistor is a first power transistor, and the control circuit is a first control circuit, and the first power transistor and the first control circuit are high-side components of the power electronic circuit, and
the power electronic circuit includes:
a second power transistor having:
a gate coupled to a second control circuit, and
a source coupled to a third contact pad wherein the second control circuit is coupled to a fourth contact pad, and the second power transistor and the second control circuit are low-side components of the power electronic circuit, and
the first and second contact pads are configured to receive different electrical supply potentials when the power electronic circuit is in a configuration for stress testing the gates of the first and second power transistors, and
the third and fourth contact pads are configured to be decoupled from each other and to receive different electrical reference potentials when the power electronic circuit is in the configuration for stress testing the gates of the first and second power transistors, and the third and fourth contact pads are configured to be coupled to each other when the first and second power transistors and the first and second control circuits are encapsulated.

16. The DC-DC converter according to claim 15, wherein a drain of the first power transistor is coupled to a first switching pad, and a drain of the second power transistor is coupled to a second switching pad, and wherein the first and second switching pads are configured to be decoupled from each other when the power electronic circuit is in the configuration for stress testing the gates of the first and second power transistors and the first and second switching pads configured to be coupled to each other when the first and second power transistors and the first and second control circuits are encapsulated.

17. A method, comprising:
performing a stress test on a gate of a power transistor of a power electronic circuit, wherein the power electronic circuit includes:
a first contact pad;
a second contact pad;
a control circuit; and
a power transistor having:
a gate coupled to the control circuit, and a source coupled to the first contact pad,
wherein the control circuit is coupled to the second contact pad;
decoupling the first and second contact pads from each other when the power electronic circuit is in a configuration for stress testing the gate of the power transistor; and
coupling the first and second contact pads to each other when the power transistor and control circuit are encapsulated.

18. The method according to claim 17, wherein stress testing the gate of the power transistor includes measuring a leakage current on the first contact pad or on a third contact pad.

19. The method according to claim 17, wherein encapsulating the power transistor and control circuit includes performing a first electrical connection electrically coupling the first and second contact pads of the power electronic circuit, and, when the power electronic circuit includes third and fourth contact pads, performing a second electrical connection coupling together the third and fourth contact pads.

20. The method according to claim 19, wherein encapsulating the power transistor and control circuit includes performing a third electrical connection coupling together the first and second switching pads of the power electronic circuit.
